(19) United States
(12) Patent Application Publication
(10) Pub. No.: US 2002/0074142 A1
(43) Pub. Date: Jun. 20, 2002

(54) Radiation protection shield for electronic devices

(76) Inventor: Joseph M. Katz, Old Westbury, NY (US)

Correspondence Address: Christopher G. Trainor, Esq., DILWORTH & BARRESE, LLP, 333 Earle Ovington Blvd., Uniondale, NY, 11553, US

(21) Appl. No.: 09/928,521

(22) Filed: Aug. 13, 2001

Related U.S. Application Data
(60) Provisional application No. 60/224,709, filed on Aug. 11, 2000.

(51) Int. Cl. H05K 9/00

(52) U.S. Cl. 174/35 R; 174/35 GC; 361/816

(57) ABSTRACT

A radiation protection shield for electronic devices is provided to shield a user from electro-magnetic and microwave radiation emitted from an electronic device. The radiation shield may be inexpensively manufactured by punching or die cutting sheets of material. Fastening components are provided which allow the shield to be adjustably fitted on a variety of differently sized and configured electronic devices. An additional shielding member is also provided for enhanced shielding in the area of the electronic device adjacent an antenna.

This application claims priority from U.S. provisional application Serial No. 60/224,709 (“the '709 application”) filed Aug. 11, 2000. The '709 application is incorporated herein by reference.

### BACKGROUND

1. Technical Field

The present disclosure relates generally to a protective shield for shielding a user of an electronic device from electro-magnetic and microwave radiation associated with operation of the device. More particularly, the present disclosure relates to an adjustable shield for shielding a user from electro-magnetic and microwave radiation emitted from any one of a variety of differently sized and configured electronic devices including handheld communication devices, e.g., cellular phones and mobile phones, and electronic games.

2. Background of the Related Art

The use of portable electronic devices such as portable telephones has increased drastically in recent years and is expected to continue to do so well into the new millennium. Accordingly, exposure to electro-magnetic and microwave radiation emitted from such electronic devices has become a growing concern. Excessive exposure has been thought to be the cause of bodily injury including different types of cancer, e.g., brain tumors.

One such electronic device which is widely used is the portable telephone. The portable telephone broadcasts and receives messages through a mouthpiece and an earphone setup which are received and transmitted through an antenna attached to the telephone. The telephone is powered from a power source, e.g., a portable battery, which emits electro-magnetic and microwave radiation. This radiation is emitted in close proximity to a persons head, i.e., the antenna is positioned between the persons ear and mouth for extended periods of time and is suspected to be dangerous to the user. Such exposure to electro-magnetic and microwave radiation so close to a persons head is dangerous, particularly in light of scientific discoveries that concluded the brain contains its own type of magnet. It is believed by some that the danger from electro-magnetic and microwave radiation exists because the magnet in the brain attracts the emitted electro-magnetic and microwave rays which over time could have a detrimental effect on the brain cells.

Accordingly, a need exists for a device which can be cheaply manufactured and adjusted to accommodate differently sized and configured electronic devices, and will protect users of electronic devices, such as portable phones, from electro-magnetic and microwave radiation by providing a shield around the electronic device to minimize the negative effect of the radiation upon a user's body. See, for example, U.S. Pat. Nos. 5,336,896 and 5,535,439 both of which are herein incorporated by reference in their entirety.

### SUMMARY

In accordance with the present disclosure, a radiation protection shield for electronic devices is provided to shield a user from electro-magnetic and microwave radiation emitted from an electronic device. The radiation shield may be inexpensively manufactured by punching or die cutting the desired configuration from sheets of material. Fastening components are provided which allow the shield to be adjustably fitted or folded about a variety of differently sized and configured electronic devices. An additional shielding member is also provided to enhance the shielding effect in the area adjacent the antenna of an electronic device.

### BRIEF DESCRIPTION OF THE DRAWINGS

Various preferred embodiments of the presently disclosed radiation shield are described herein with reference to the drawings, wherein:

FIG. 1 is a side view of the presently disclosed radiation protection shield in prefolded condition;

FIG. 2 is a front view of the radiation protection shield shown in FIG. 1 positioned about a portable telephone;

FIG. 3 is a side view of the radiation protection shield shown in FIG. 1 positioned about a portable telephone;

FIG. 4 is a top view of the radiation protection shield shown in FIG. 1 positioned about a portable telephone; and

FIG. 5 is a side view of the radiation protection shield shown in FIG. 1 positioned about a portable telephone.

### DETAILED DESCRIPTION OF PREFERRED EMBODIMENTS

Preferred embodiments of the presently disclosed radiation protection shield will now be described in detail with reference to the drawings in which like reference numerals designate identical or corresponding elements in each of the several views.

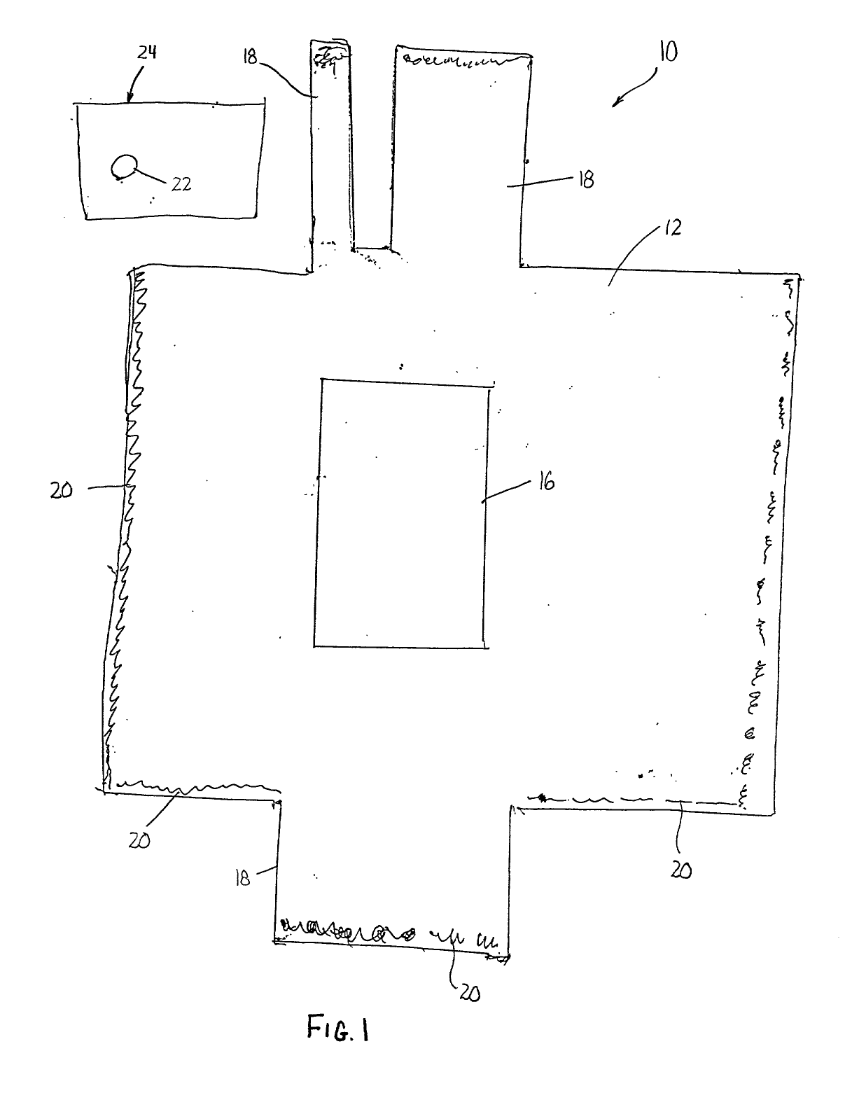

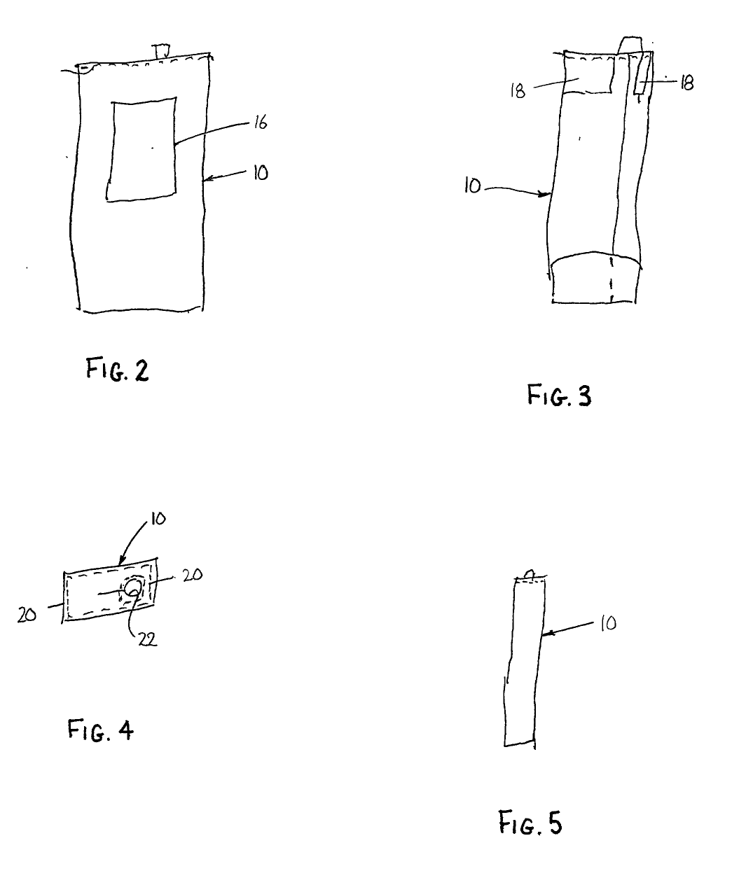

FIGS. 1-5 illustrate one preferred embodiment of the presently disclosed radiation protection shield shown generally as 10. Shield 10 is formed as a flat sheet of material which is preferably punched out or die cut into the desired configuration in large quantities by the manufacturer during production. Alternately, other manufacturing techniques may be used to form shield 10. The particular configuration of shield 10 need not be as shown but rather may be adapted to provide shielding for any electronic device. Shield 10 includes an inner layer 12 formed at least partially of commercially available radiation protection shielding. An outer layer 14 of shield 10 is preferably formed from an aesthetically pleasing material such as leather, fabric, plastic, etc. Alternately, other materials may be used to form the outer surface of shield 10 or outer surface 14 may be entirely omitted. Inner and outer layers 12 and 14 are firmly attached together using a known fastening technique, e.g., adhesive or stitching. Outer layer 14 preferably includes a shielded window 16 to allow the user to view a display on the electronic device to be enclosed, e.g., telephone keypad, interactive keys, etc.

Shield 10 includes a number of flaps 18 which can be folded about an electronic device to enclose the electronic device. Although four flaps are shown, the use of a different number of flaps is envisioned. Each of flaps 18 has a fastener component 20 formed on a distal end of the inner surface of flap 18. Although fastener component 20 is illustrated in FIG. 1 as hook and loop fasteners, other fastening components may be provided including buttons, snaps, etc. A corresponding fastener component (not shown) is formed on an outer surface of each flap. The corresponding fastener, e.g., hook and loop fasteners, snaps, etc., are preferably dimensioned or arranged to facilitate adjustment of shield 10 about an electronic device. More specifically, if hook and loop fasteners are provided, the hook and loop fasteners on one of the inner and outer surfaces of the flaps should be dimensioned to allow for a large degree of shield adjustment. Moreover, if buttons or snaps are provided, a plurality of snaps or buttons are preferably provided to allow for adjustment of shield 10 about the electronic device. By providing an adjustable shield, shield 10 is able to accommodate a multiplicity of differently sized and configured electronic devices.

In order to ensure adequate shielding of an electronic device having an antenna, shield 10 includes a separate antenna shield 24 having a hole 22 dimensioned to allow passage of an antenna. Antenna shield 24 is positionable about the antenna of an electronic such that shield 24 covers the area of the electronic device about the antenna.

In use, an electronic device to be enclosed is simply placed face down onto shielded window 16 and flaps 18 are folded around the device in order to form the shielded envelope or case. The outer edges of flaps 18 having the fastener components 20 formed thereon are interfaced to securely envelope the electronic device. When the electronic device to be enclosed includes a protrusion such as an antenna, the antenna shield 24 having hole 22 for the antenna is passed over the antenna to a position on top of the device to be enclosed about the antenna. Thereafter, shield 10 is positioned and secured about the electronic device in the manner discussed above such that antenna shield 24 is positioned between the electronic device and shield 10. The electronic device is now ready to use and is radiation shielded.

Although the illustrative embodiments of the present disclosure have been described herein with reference to the accompanying drawings, it is to be understood that the disclosure is not limited to those precise embodiments, and that various other changes and modifications may be affected therein by one skilled in the art without departing from the scope or spirit of the invention. All such changes and modifications are intended to be included within the scope of the presently disclosed radiation protection shield.

What is claimed is:

1. A radiation protection shield for an electronic device comprising:
a first sheet of material having top and bottom surfaces, the sheet of material having a plurality of flaps, the sheet of material and flaps including fastening components to allow the material to be folded about and secured to differently sized and shaped electronic devices, wherein the sheet of material is formed at least partly from radiation shielding material.

2. A radiation protection shield according to claim 1, further including a shielded window to facilitate viewing of interactive keys or display screen of the electronic device.

3. A radiation protection shield according to claim 2, wherein the fastening components are hook and loop fasteners.

4. A radiation protection shield according to claim, 2, further including a second sheet of material, the second sheet of material being formed of an aesthetically pleasing material and being secured in juxtaposed relation to the first sheet of material.

5. A radiation protection shield according to claim 4 wherein the second sheet of material is selected from the group consisting of fabric, leather, and plastic.

6. A radiation protection shield according to claim 1, wherein the fastening components are provided on the flaps.

7. A radiation protection shield according to claim 6, wherein the plurality off laps includes four flaps.

8. A radiation protection shield according to claim 1, further including an antenna shield, the antenna shield having a hole dimensioned to receive an antenna of an electronic device.
